(19) United States
(12) Patent Application Publication
(10) Pub. No.: US 2004/0135209 A1
(43) Pub. Date: Jul. 15, 2004

(54) Camera with MOS or CMOS sensor array

(76) Inventors: Tzu-Chiang Hsieh, Fremont, CA (US); Calvin Chao, Cupertino, CA (US)

Correspondence Address: John R. Ross, TREX ENTERPRISES, 10455 Pacific Center Ct., San Diego, CA, 92121, US

(21) Appl. No.: 10/746,529

(22) Filed: Dec. 23, 2003

Related U.S. Application Data
(63) Continuation-in-part of application No. 10/072,637, filed on Feb. 5, 2002, now Pat. No. 6,730,914.
(63) Continuation-in-part of application No. 10/229,953, filed on Aug. 27, 2002.
(63) Continuation-in-part of application No. 10/229,954, filed on Aug. 27, 2002.
(63) Continuation-in-part of application No. 10/229,955, filed on Aug. 27, 2002.
(63) Continuation-in-part of application No. 10/229,956, filed on Aug. 27, 2002.
(63) Continuation-in-part of application No. 10/371,618, filed on Feb. 22, 2003, now Pat. No. 6,730,900.
(63) Continuation-in-part of application No. 10/648,129, filed on Aug. 26, 2003.

(51) Int. Cl. H01L 29/76

(52) U.S. Cl. 257/368

(57) ABSTRACT

The present invention provides a novel MOS or CMOS based active sensor array for producing electronic images from electron-hole producing light. Each pixel of the array includes a layered photodiode for converting the electron-hole producing light into electrical charges and MOS and/or CMOS pixel circuits located under the layered photodiodes for collecting the charges. The present invention also provides additional MOS or CMOS circuits in and/or on the same crystalline substrate for processing the collected charges for the purposes of producing images. The layered photodiode of each pixel is fabricated as continuous layers of charge generating material on top of the MOS and/or CMOS pixel circuits so that extremely small pixels are possible with almost 100 percent packing factors. In preferred embodiments, pixel crosstalk is minimized by careful design of the bottom photodiode layer with the addition of carbon to the doped amorphous silicon N or P layer to increase the electrical resistivity.

### FIELD OF THE INVENTION

This application is a continuation in part of U.S. patent application Ser. No. 10/072,637 filed Feb. 5, 2002, Ser. No. 10/229,953 filed Aug. 27, 2002, Ser. No. 10/229,954 filed Aug. 27, 2002, Ser. No. 10/229,955 filed Aug. 27, 2002, Ser. No. 10/229,956 filed Aug. 27, 2002, Ser. No. 10/371,618 filed Feb. 22, 2003 and Ser. No. 10/648,129 filed Aug. 26, 2003; all incorporated herein by reference. The present invention relates to cameras and in particular to cameras with MOS or CMOS sensors.

### BACKGROUND OF THE INVENTION

Electronic image sensors are typically comprised of pixel arrays of a large number of very small light detectors, together called “pixel arrays”. These sensors typically generate electronic signals that have amplitudes that are proportional to the intensity of the light received by each of the detectors in the array. Electronic cameras comprise imaging components to produce an optical image of a scene onto the pixel array. The electronic image sensors convert the optical image into a set of electronic signals. These electronic cameras typically include components for conditioning and processing the electronic signals to allow images to be converted into a digital format so that the images can be processed by a digital processor and/or transmitted digitally. Various types of semiconductor devices can be used for acquiring the image. These include charge couple devices (CCDs), photodiode arrays and charge injection devices. The most popular electronic image sensors utilize arrays of CCD detectors for converting light into electrical signals. These detectors have been available for many years and the CCD technology is mature and well developed. One big drawback with CCD's is that the technique for producing CCD's is incompatible with other integrated circuit technology such as MOS and CMOS technology, so that processing circuits and the CCD arrays must be produced on chips separate from the CCD's.

Another currently available type of image sensors is based on metal oxide semiconductor (MOS) technology or complementary metal oxide semi-conductor (CMOS) technology. These sensors are commonly referred to as CMOS sensors. CMOS sensors have multiple transistors within each pixel. The most common CMOS sensors have photo-sensing circuitry and active circuitry designed in each pixel cell. They are called active pixel sensors (APS's). The active circuitry consists of multiple transistors that are inter-connected by metal lines; as a result, this area is opaque to visible light and cannot be used for photo-sensing. Thus, each pixel cell typically comprises photosensitive and non-photosensitive circuitry. In addition to circuitry associated with each pixel cell, CMOS sensors have other digital and analog signal processing circuitry, such as sample-and-hold amplifiers, analog-to-digital converters and digital signal processing logic circuitry, all integrated as a monolithic device. Both pixel arrays and other digital and analog circuitry are fabricated using the same basic process sequence.

Small cameras which utilize CCD arrays to convert an optical image to an electronic image have been commercially available for many years. Also, attempts have been made to produce small visible light cameras using CMOS sensors on the same chip with processing circuits. One such attempt is described in recently issued U.S. Pat. No. 6,486,503.

Small cameras using CCD sensors consume large a mounts of energy (as compared to cameras with CMOS sensors) and require high rail-to-rail voltage swings to operate CCD. This can pose problems for today's mobile appliances, such as Cellular Phone and Personal Digital Assistant. On the other hand, small cameras using CMOS sensors may provide a solution for energy consumption; but the traditional CMOS-based small cameras suffer low light sensing performance, which is intrinsic to the nature of CMOS APS sensors caused by shallow junction depth in the silicon substrate and its active transistor circuitry taking away the real estate preciously needed for photo-sensing.

U.S. Pat. Nos. 5,528,043 5,886,353, 5998,794 and 6,163,030 are examples of prior art patents utilizing CMOS circuits for imaging which have been licensed to Applicants' employer. U.S. Pat. No. 5,528,043 describes an X-ray detector utilizing a CMOS sensor array with readout circuits on a single chip. In that example image processing is handled by a separate processor (see FIG. 4 which is FIG. 1 in the '353 patent. U.S. Pat. No. 5,886,353 describes a generic pixel architecture using a hydrogenated amorphous silicon layer structure, either p-i-n or p-n or other derivatives, in conjunction with CMOS circuits to for the pixel arrays. U.S. Pat. Nos. 5,998,794 and 6,163,030 describe various ways of making electrical contact to the underlying CMOS circuits in a pixel. All of the above US patents are incorporated herein by reference.

Combining CMOS and MOS sensors with external processors can result in complexity and increase production costs. A need exists for improved camera technology which can provide cameras with cost, quality and size improvements over prior art cameras.

### SUMMARY OF THE INVENTION

The present invention provides a novel MOS or CMOS based active sensor array for producing electronic images from electron-hole producing light. Each pixel of the array includes a layered photodiode for converting the electron-hole producing light into electrical charges and MOS and/or CMOS pixel circuits located under the layered photodiodes for collecting the charges. The present invention also provides additional MOS or CMOS circuits in and/or on the same crystalline substrate for processing the collected charges for the purposes of producing images. The layered photodiode of each pixel is fabricated as continuous layers of charge generating material on top of the MOS and/or CMOS pixel circuits so that extremely small pixels are possible with almost 100 percent packing factors. In preferred embodiments, pixel crosstalk is minimized by careful design of the bottom photodiode layer with the addition of carbon to the doped amorphous silicon N or P layer to increase the electrical resistivity.

In a first preferred embodiment the sensor is a 0.3 mega pixel (3.2 mm×2.4 mm, 640×480) array of 5 micron square pixels which is compatible with a lens of 1/4.5 inch optical format. In a preferred embodiment the sensor along with focusing optics is incorporated into a cellular phone camera or a camera attachment the cellular phone to permit transmission of visual images along with the voice communication. All of the camera circuits are incorporated on or in a single crystalline substrate along with the sensor pixel circuits. The result is an extremely low cost camera at high volume production that can be made extremely small (e.g., smaller than the human eye). High volume production costs for the above 0.3 mega-pixel camera are projected to be less than $10 per camera.

In a second preferred embodiment the sensor includes a two-million pixel array of 5-micron wide pixels. This sensor is especially useful for a high-definition television camera.

### BRIEF DESCRIPTION OF THE DRAWINGS

FIGS. 1A and 1B are drawings of cellular phones with equipped with a camera utilizing a camera with a CMOS sensor array according to the present invention.

FIG. 1C shows some details of the camera.

FIG. 2 shows some details of a CMOS integrated circuit utilizing some of the principals of the present invention.

FIG. 3A is a partial cross-sectional diagram illustrating pixel cell architecture for five pixels of a sensor array utilizing principles of the present invention.

FIG. 3B shows CMOS pixel circuitry for a single pixel.

FIG. 3C shows a color filter grid pattern.

FIGS. 4A, B and C show features of a 2 million pixel sensor.

FIG. 5 shows a pixel array layout for the 2 million pixel sensor.

FIG. 6 shows a technique for amplifying and converting an analog sensor signal to digital data.

FIG. 7 shows a column-based signal chain.

FIG. 8 shows a digital signal processing chain.

FIG. 9 shows the checkerboard color filter array.

### DETAILED DESCRIPTION OF A PREFERRED EMBODIMENT

In the following description of preferred embodiments, reference is made to the accompanying drawings, which form a part hereof, and which show by way of illustration a specific embodiment of the invention. It is to be understood by those of working skill in this technological field that other embodiments may be utilized, and structural, electrical, as well as procedural changes may be made without departing from the scope of the present invention.

### Tiny 0.3 Mega Pixel Camera

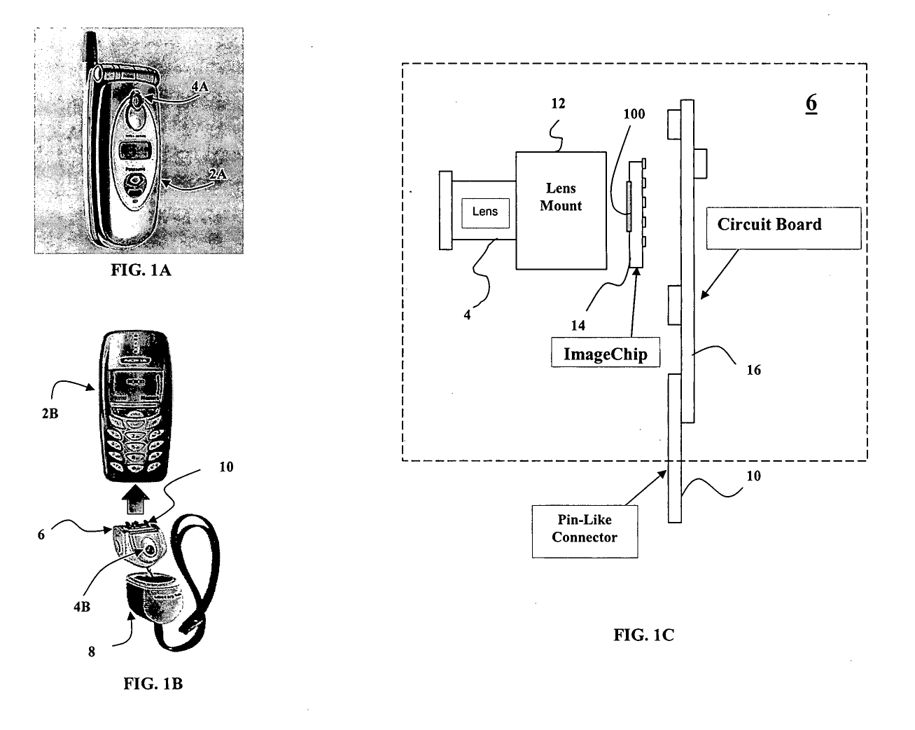

A preferred embodiment of the present invention is a single chip camera with a sensor consisting of a photodiode array consisting of photoconductive layers on top of an active array of CMOS circuits. (Applicants refer to this sensor as a “POAP Sensor” the “POAP” referring to “Photoconductor On Active Pixel”.) In this sensor there are 307,200 pixels arranged in as a 640×480 pixel array and there is a transparent electrode on top of the photoconductive layers. The pixels are 5 microns×5 microns and the packing fraction is approximately 100 percent. The active dimensions of the sensor are 3.2 mm×2.4 mm and a preferred lens unit is a standard lens with a 1/4.5 inch optical format. A preferred application of the camera is as a component of a cellular phone as shown in FIGS. 1A and 1B. In the 1A drawing the camera is an integral part of the phone 2A and the lens is shown at 4A. In the 1B drawing the camera 6 is separated from the phone 2B and connected to it through the 3 pin-like connectors 10. The lens of the camera is shown at 4B and a camera protective cover is shown at 8. FIG. 1C is a block diagram showing the major features of the camera 4B shown in FIG. 1B drawing. They are lens 4, lens mount 12, image chip 14, sensor pixel array 100, circuit board 16, and pin-like connector 10.

### CMOS Sensor

The sensor section is implemented with a photoconductor on active pixel array, readout circuitry, readout timing/control circuitry, sensor timing/control circuitry and analog-to-digital conversion circuitry. The sensor includes:

1) a CMOS-based pixel array comprised 640×480 charge collectors and 640×480 CMOS pixel circuits and

2) a CMOS readout circuit.

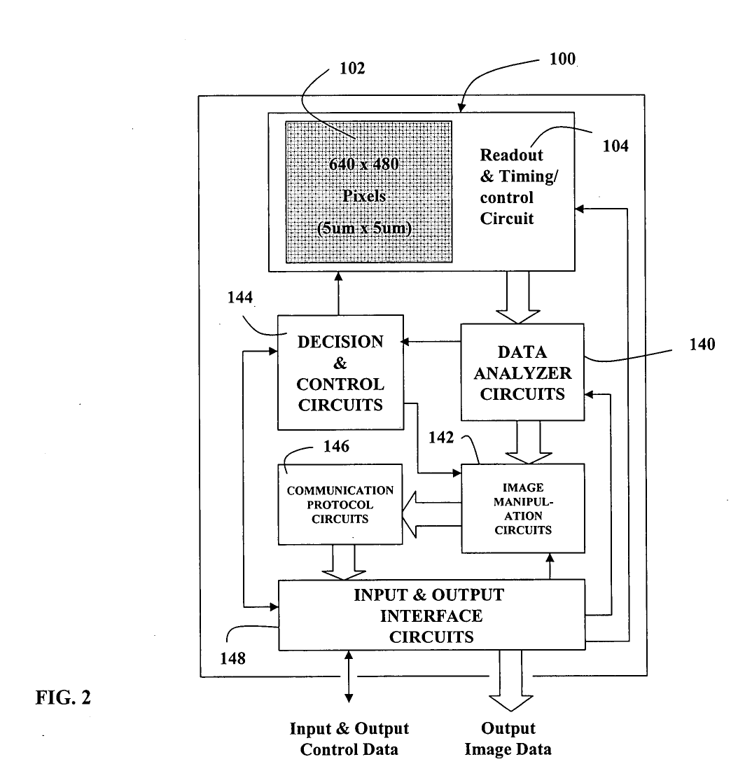

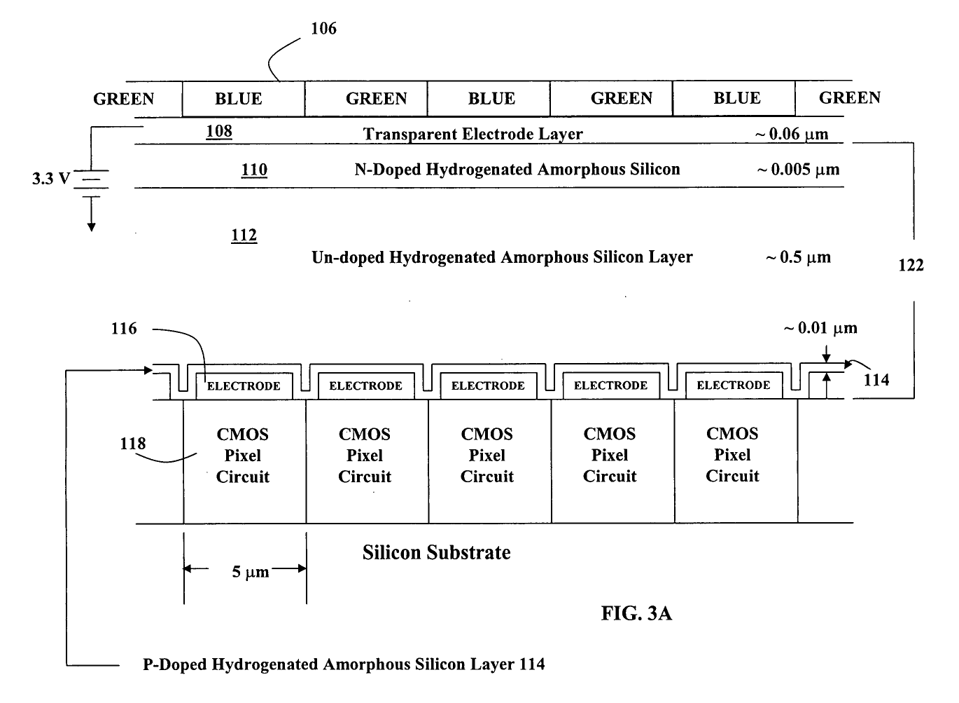

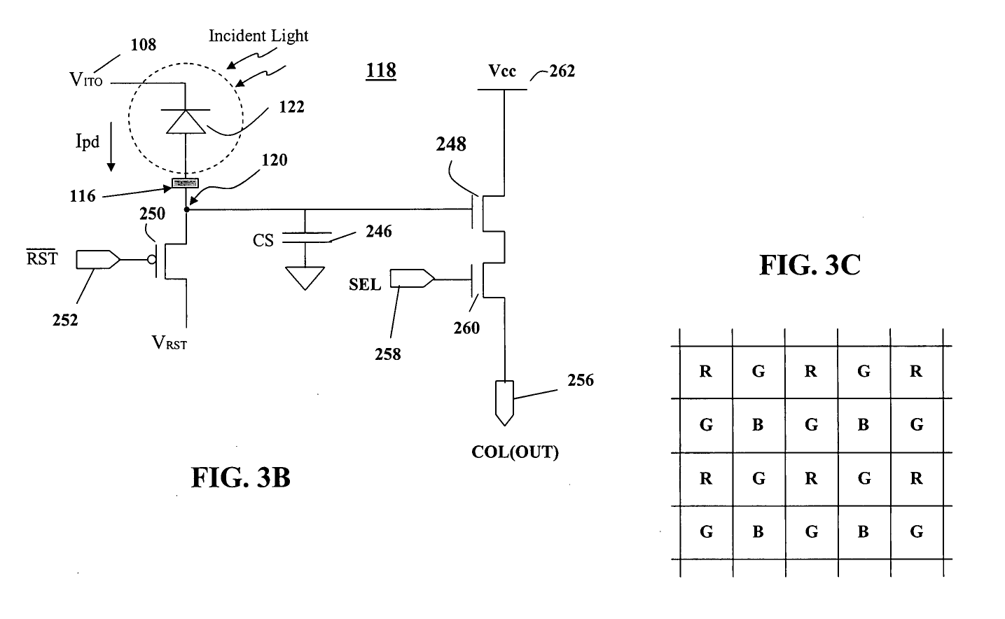

The sensor array is similar to the visible light sensor array described in U.S. Pat. No. 5,886,353 (see especially text at columns 19 through 21 and FIG. 27) that is incorporated by reference herein. Details of various sensor arrays are also described in the parent patent applications referred to in the first sentence of this specification all of which have also been incorporated herein by reference. FIGS. 2, 3A, 3B and 3C describe features of a preferred sensor array for this cell phone camera. The general layout of the sensor is shown at 100 in FIG. 2. The sensor includes the pixel array 102 and readout and timing/control circuitry 104. FIG. 3A is a drawing showing the layered structure of a 5 pixel section of the pixel array.

The sensor array is coated with color filters and each pixel is coated with only one color filter to define only one component of the color spectrum. The preferred color filters set is comprises three broadband color filters with peak transmission at 450 nm (B), 550 nm (G) and 630 nm (R). The full width of half maximum of the color filters is about 50 nm for Blue and Green filters. The Red filter typically has transmission all the way into near infrared. For visible image application, an IR cut-off filter needs to be used to tailor the Red response to be peaked at 630 nm with about 50 nm full width of half maximum. These filters are used for visible light sensing applications. Four pixels are formed as a quadruplet, as shown in FIG. 3C. Two of the four pixels are coated with color filter of peak transmission at 550 nm, they are referred as “Green pixels”. One pixel is coated with color filter with peak at 450 nm (Blue pixel) and one with filter peaked at 630 nm (Red pixel). The two Green pixels are placed at the upper-right and lower-left quadrants. A Red pixel is placed at the upper-left quadrant and a Blue pixel is placed at lower-right quadrant. The color-filter-coated quadruplets are repeated for the entire 640×480 array. FIG. 3A shows a top filter layer 106 in which the green and blue filters alternate across a row of pixels. Beneath the filter layer is a transparent surface electrode layer 108 comprised of about 0.06 micron thick layer of indium tin oxide which is electrically conductive and transmissive to visible light. Below the conductive surface electrode layer is a photoconductive layer comprised of three sub-layers. The uppermost sub-layer is an about 0.005 micron thick layer 110 of n-doped hydrogenated amorphous silicon. Under that layer is an about 0.5 micron layer 112 of un-doped hydrogenated-amorphous silicon. This 112 layer is referred to by Applicants as an “intrinsic” layer. This intrinsic layer is the one that displays high electrical resistivity unless it is illuminated by photons. Under the un-doped layer is an about 0.01 micron layer 114 of high-resistivity P-doped hydrogenated-amorphous silicon. These three hydrogenated amorphous silicon layers produce a diode effect above each pixel circuit. Applicants refer to the layers as a N-I-P photoconductive layer. Carbon atoms or molecules may be added to layer 114 to increase electrical resistance. This would minimize the lateral crosstalk among pixels and avoids loss of spatial resolution. This N-I-P photoconductive layer is not lithographically patterned, but (in the horizontal plane) is a homogeneous film structure. This simplifies the manufacturing process. Within the sub-layer 114 are 307,200 4.6×4.6 micron electrodes 116 which define the 307,200 pixels in this preferred sensor array. Electrodes 116 are made of titanium nitride (TiN). Just below the electrodes 116 are CMOS pixel circuits 118. The components of pixel circuits 118 are described by reference to FIG. 3B. The CMOS pixel circuits 118 utilize three transistors 250, 248 and 260. The operation of a similar three transistors pixel circuit is described in detail in U.S. Pat. No. 5,886,353. This circuit is used in this embodiment to achieve maximum saving in chip area. Other more elaborate readout circuits are described in the parent patent applications referred to in the first sentence of this specification. Pixel electrode 116, shown in FIG. 3A, is connected to the charge-collecting node 120 as shown in FIG. 3B. Pixel circuit 118 includes charge collection node 120, collection capacitor 246, source follower buffer 248, selection transistor 260, and reset transistor 250. Pixel circuit 118 uses p-channel transistors for reset transistor 250 and an n-channel transistor for source follower transistor 248 and selection transistor 260. The voltage at COL (out) 256 is proportional to the charge Q (in) stored on the collection capacitor 246. By reading this node twice, once after the exposure to light and once after the reset, the voltage difference is a direct proportional to the amount of light being detected by the Photo-sensing structure 122. Pixel circuit 118 is referenced to a positive voltage Vcc at node 262 (typically 2.5 to 5 Volts). Pixel circuitry for this array is described in detail in the '353 patent.

### Other Camera Features

In this preferred embodiment, as shown in FIG. 2 additional MOS or CMOS circuits for converting the charges into electrical signal, for amplifying the signals, for converting analog signal into digital signal and for digital signal processing are provided on the same crystalline substrate utilized for the collection of the charges. The data out of the sensor section 100 is in digital form and with a pixel-sequential stream. The sensor chip area includes a standard clock generation feature (not shown here but described in the '353 patent). From it, signals representing the start of frame, start of line, end of a frame, end of line and pixel are distributed into all sections on the image chip to synchronize the data flow.

Environmental Analyzer Circuits:

The data out of the sensor section is fed into an environmental analyzer circuit 140 where image's statistics is calculated. The sensor region is preferably partitioned into separate sub-regions, with the average or mean signal within the region being compared to the individual signals within that region in order to identify characteristics of the image data. For instance, the following characteristics of the lighting environment are measured:

1. light source brightness at the image plane

2. light source spectral composition for white balance purpose

3. imaging object reflectance

4. imaging object reflectance spectrum

5. imaging object reflectance uniformity

The measured image characteristics are provided to decision and control circuits 144. The image data passing through an environmental analyzer circuit 140 are preferably not be modified by it at all. In this embodiment, the statistics include the mean of the first primary color signal among all pixels, the mean of the second primary color signal, the mean of the third primary color signal and the mean of the luminance signal. This circuit will not alter the data in any way but calculate the statistics and pass the original data to image manipulation circuits 142 other statistical information, such as maximum and minimum will be calculated as well. They can be useful in terms of telling the range of the object reflectance and lighting condition. The statistics for color information is on full image basis, but the statistics of luminance signal is on a per sub-image regions basis. This implementation permits the use of a weighted average to emphasize the importance of one selected sub-image, such as the center area.

Decision & Control Circuits:

The image parameter signals received from the environmental analyzer 140 are used by the decision and control circuits 144 to auto-exposure and auto-white-balance controls and to evaluate the quality of the image being sensed, and based on this evaluation, the control module (1) provide feedback to the sensor to change certain modifiable aspects of the image data provided by the sensor, and (2) provide control signals and parameters to image manipulation circuits 142. The change can be sub-image based or full-image based. Feedback from the control circuits 144 to the sensor 100 provides active control of the sensor elements (substrate, image absorption layer, and readout circuitry) in order to optimize the characteristics of the image data. Specifically, the feedback control provides the ability to program the sensor to change operation (or control parameters) of the sensor elements. The control signals and parameters provided to the image manipulation circuits 142 may include certain corrective changes to be made to the image data before outputting the data from the camera.

Image Manipulation Circuits:

Image manipulation circuit 142 receives the image data from the environmental analyzer and, with consideration to the control signals received from the control module, provides an output image data signal in which the image data is optimized to parameters based on the control algorithm. In these circuits, pixel-by-pixel image data are processed so each pixel is represented by three color-primaries. Color saturation, color hue, contrast, brightness can be adjusted to achieve desirable image quality. The image manipulation circuits provide color interpolation between each pixel and adjacent pixels with color filters of the same kind so each pixel can be represented by three-color components. This provides enough information with respect to each pixel so that the sensor can mimic human perception with color information for each pixel. It further does color adjustment so the difference between the color response of sensors and human vision can be optimized.

Communication Protocol Circuits:

Communication protocol circuits 146 rearrange the image data received from image manipulation circuits to comply with communication protocols, either industrial standard or proprietary, needed for a down-stream device. The protocols can be in bit-serial or bit-parallel format. Preferably, communication protocol circuits 146 convert the process image data into luminance and chrominance components, such as described in ITU-R BT.601-4 standard. With this data protocol, the output from the image chip can be readily used with other components in the market place. Other protocols may be used for specific applications.

Input & Output Interface Circuits:

Input and output interface circuits 148 receive data from the communication protocol circuits 146 and convert them into the electrical signals that can be detected and recognized by the down-stream device. In this preferred embodiment, the input & output Interface circuits 148 provide the circuitry to allow external to get the data from the image chip, read and write information from/to the image chip's programmable parametric section.

Chip Package:

The image chip is packaged into an 8 mm×8 mm plastic chip carrier with glass cover. Depending upon the economics and applications, other type and size of chip carrier can be used. Glass-cover can be replaced by other type of transparent materials as well. The glass cover can be coated with anti-reflectance coating, and/or infrared cut-off filter. In an alternative embodiment, this glass cover is not needed if the module is hermetically sealed with a substrate on which the image chip is mounted, and assembled in a high quality clean room with lens mount as the cover.

### The Camera

Lens 4 shown in FIG. 1C is based on a 1/4.5″ F/2.8 optical format and has a fixed focal length with a focus range of 3-5 meters. Because of the smaller chip size, the entire camera module can be less than 10 mm (Length)×10 mm (Width)×10 mm (Height). This is substantially smaller than the human eyeball! This compact module size is very suitable for portable appliances, such as cellular phone and PDA. Lens mount 12 is made of black plastic to prevent light leak and internal reflectance. The image chip is inserted into the lens mount with unidirectional notches at four sides, so to be provide a single unit once the image c hip is inserted in and securely fastened. This module has metal leads on the 8 mm×8 mm chip carrier that can be soldered onto a typical electronics circuit board.

### Examples of Feedback & Control

Camera Exposure Control:

Sensor 100 can be used as a photo-detector to determine the lighting condition. Since the sensor signal is directly proportional to the light sensed in each pixel, one can calibrate the camera to have a “nominal” signal under desirable light. When the signal is lower than the “nominal” value, it means that the ambient “lighting level” is lower than desirable. To bring the electrical signal back to “nominal” level, the pixel exposure time to light and/or the signal amplification factor in sensor or in the image manipulation module are automatically adjusted. The camera may be programmed to partition the full image into sub-regions is to be sure the change of operation can be made on a sub-region basis or to have the effect weighted more on a region of interest.

Camera White Balance Control:

The camera may be used under all kind of “light sources”. Each light source has different spectral distribution. As a result, the signal out of the sensor will vary under different “light source”. However, one would like to make the image visualized similarly when displayed on a visualizing device, such as print paper or CRT display. It means that a typical light source (day light, flash light, tungsten light bulb, etc) needs to be perceived as a white object more or less. Since the sensor has pixels covered with primary color filters, one can then determine the relative intensity of the light source from the image data. The environmental analyzer is to get the statistics of the image and determine the spectral composition and make necessary parametric adjustment in sensor operation or Image Manipulation to create a signal that can be displayed as “white object” when perceived by human.

### Two Million Pixel Camera

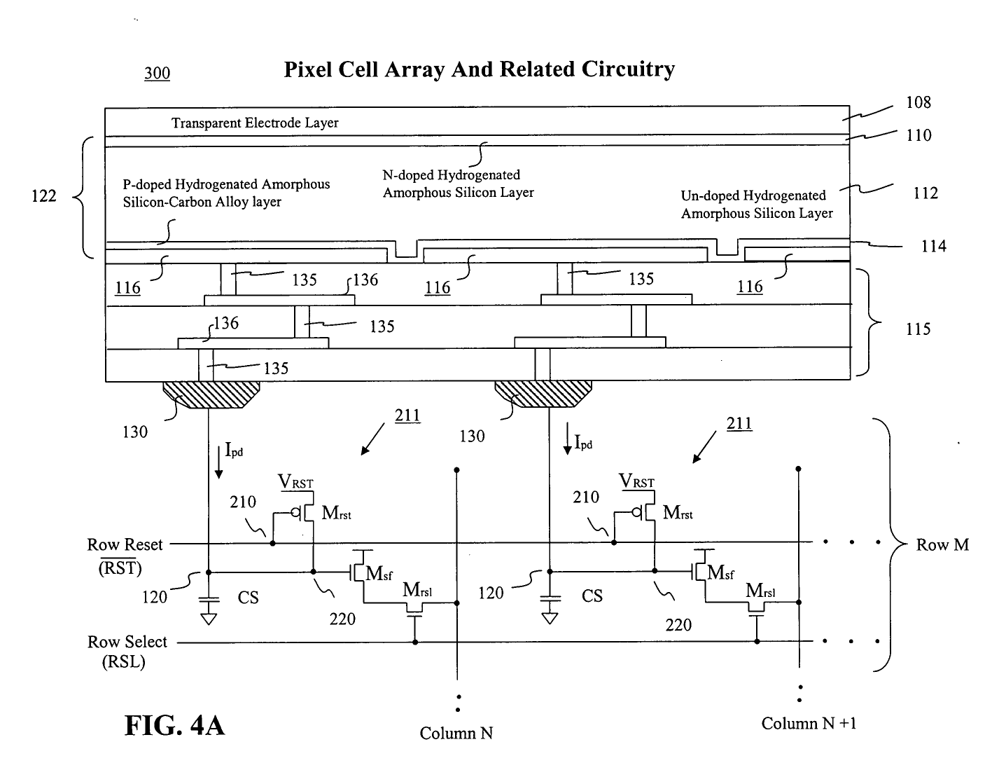

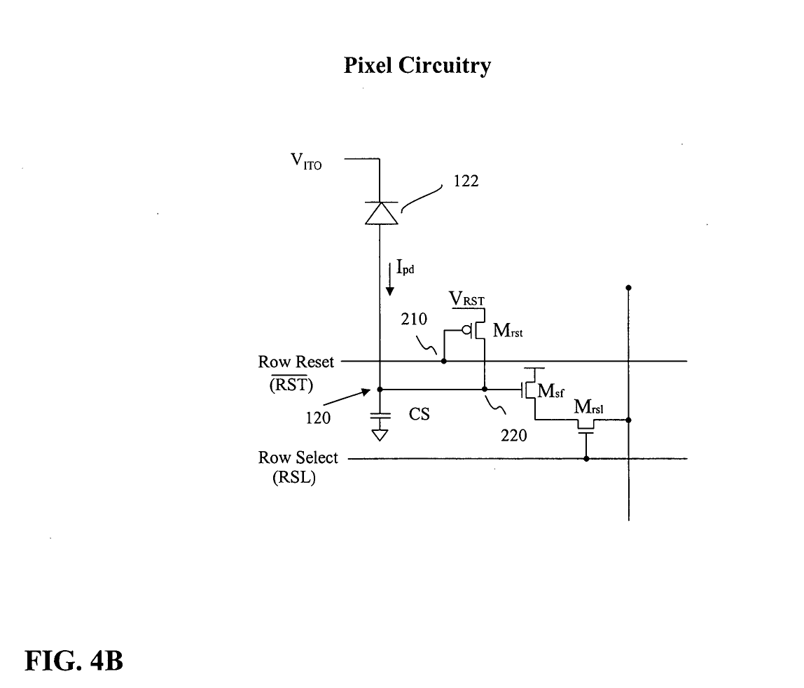

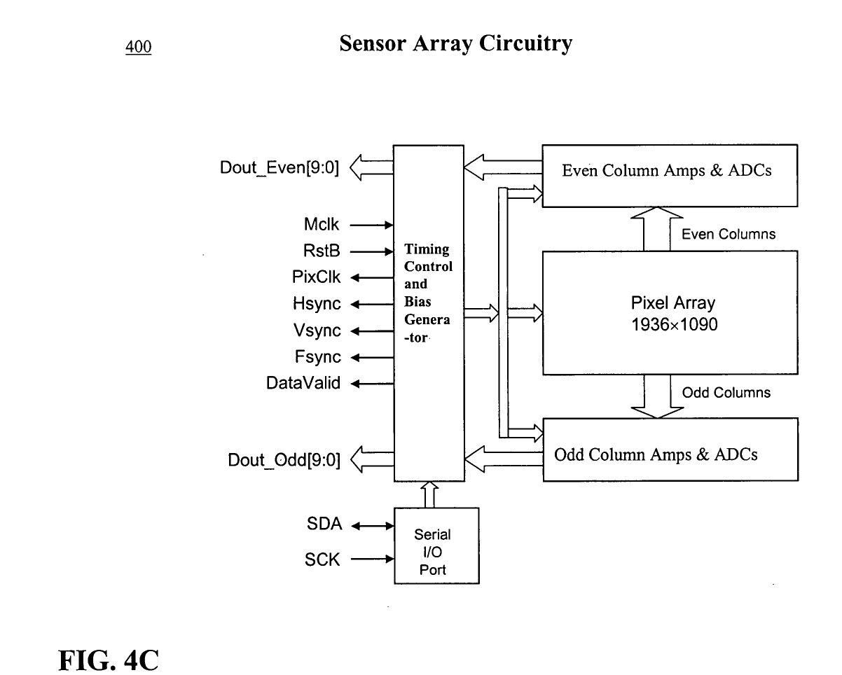

A second preferred embodiment of the present invention, which includes a two million pixels sensor array, can be described by reference to FIG. 4A through FIG. 9.

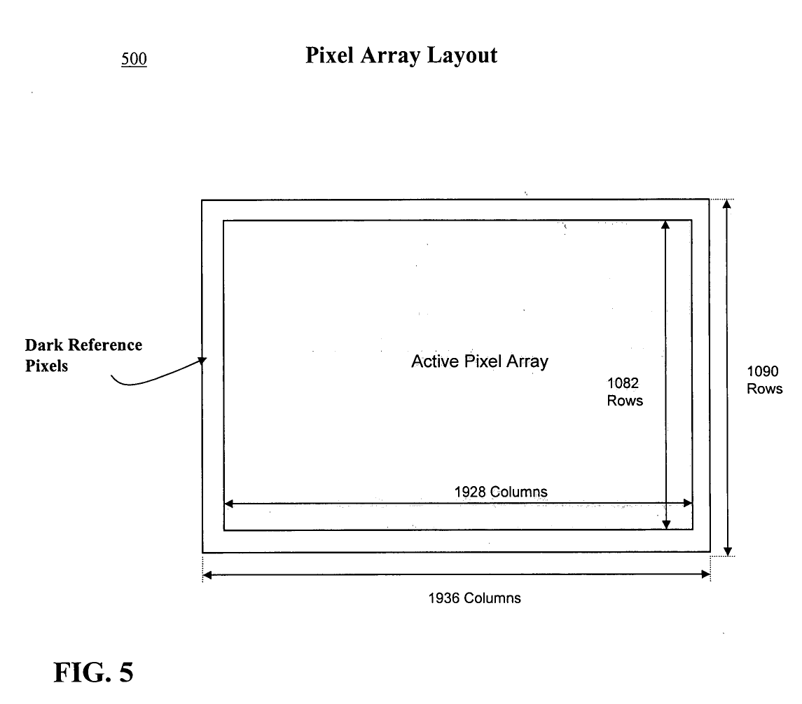

The two million pixels cell array and related circuitry is shown in FIG. 4A. A preferred pixel configuration of 1082 rows and 1928 columns is shown in FIG. 5. This sensor is well suited for producing images for high definition television. In general, the individual pixels are very similar to the pixels in the first preferred embodiment. The transistor portions of the pixels are shown at 211 as integrated circuits in electrical schematic form in FIG. 4A. FIG. 4B is an electrical schematic drawing showing the transistor portion of the pixel circuit and the photodiode portion of the pixel, all in schematic form. These integrated pixel circuits are produced in and on a silicon substrate using standard CMOS techniques. The various photodiode portions of each pixel are laid down in continuous layers on top of the integrated circuits and are shown in FIG. 4A as actual layers. Each pixel comprises an impurity-doped diffusion region 130 that is a portion of the reset transistor Mᵣₛₜ and represents a part of the charge collection node 120 as shown in FIG. 4B.

The array includes an interconnect structure 115 comprised of dielectric layers providing insulation and electrical interconnections of various elements of the pixel cell array. These interconnections include a set of vias 135 and metalized regions 136 for each pixel connecting diffusion region 130 with a patterned electrode pad 116 formed on top of the interconnect structure 115. Interconnect structure 115, and metalized regions 136 and vias 135 are produced using standard CMOS fabrication techniques. In the standard CMOS fabrication process, metal lines are formed of a stack of Titanium Nitride (TiN) and Aluminum layers, where Aluminum line is stacked on top of TiN line and TiN is making contact with vias. Because Aluminum has very high diffusivity with amorphous silicon, Applicants' embodiment has 116 made of Titanium Nitride without the top Aluminum layer. This finding is essential to make Applicants' sensor work. Of course other metals, such as Titanium, Tungsten, Titanium-Tungsten alloy and Tungsten Nitride, can be used as well. But Titanium Nitride is readily available in a typical CMOS process, therefore, it is Applicants' preferred material.

Each pixel includes a N-I-P photodiode portion formed by continuous layers laid down on top of the interconnect structure 115 and patterned electrode pads 116. The lowest of the photodiode layers, layer 114, is about 0.01 micron thick and is comprised of P-doped hydrogenated amorphous silicon. This layer is preferably also added with carbon at concentrations between about 5 to 35 percent. (Carbon concentrations as high as 50 percent could be used. In prototype devices actually built and tested by Applicants, the carbon concentration was about 30 percent.) Applicants have discovered that carbon doping at this concentration does not significantly adversely affect the quality of this layer as a p-type semiconductor but does substantially increase the electrical resistivity of the layer. This issue is discussed in more detail below. The next higher layer, layer 112 is the intrinsic layer of the N-I-P photodiode region of the array. It is hydrogenated amorphous silicon and no doping and is in this embodiment about 0.5 to 1.0 micron thick. The top photodiode layer 110 is N-doped hydrogenated amorphous silicon and is about 0.005 to 0.01 micron thick. A transparent electrode layer 108 is a layer of indium tin oxide deposited on top of N-layer 108 about 0.06 micron thick. This material is electrically conductive and also transparent to visible light.

### Pixel Circuitry

The electronic components of each pixel in this embodiment are shown in FIG. 4B are the same as those shown in FIG. 3B for the 0.3 mega pixel camera. The reader is referred to the description given above with a reference to FIG. 3B for an understanding of the pixel circuitry.

### Sensor Array Circuitry

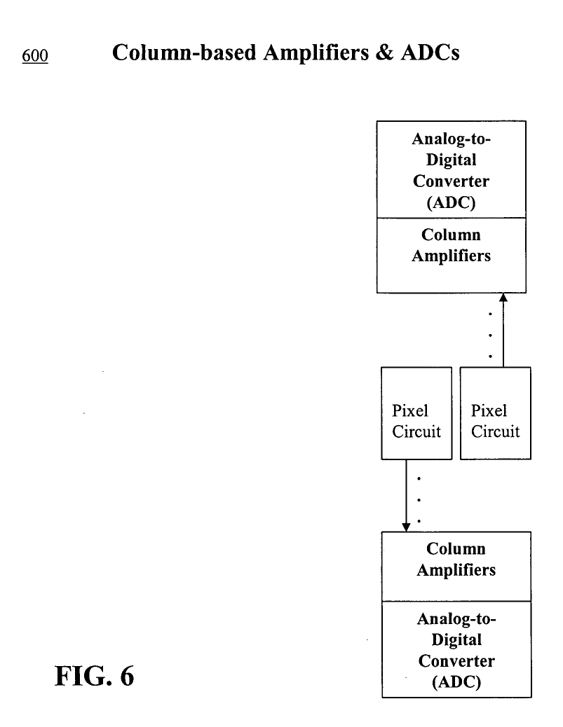

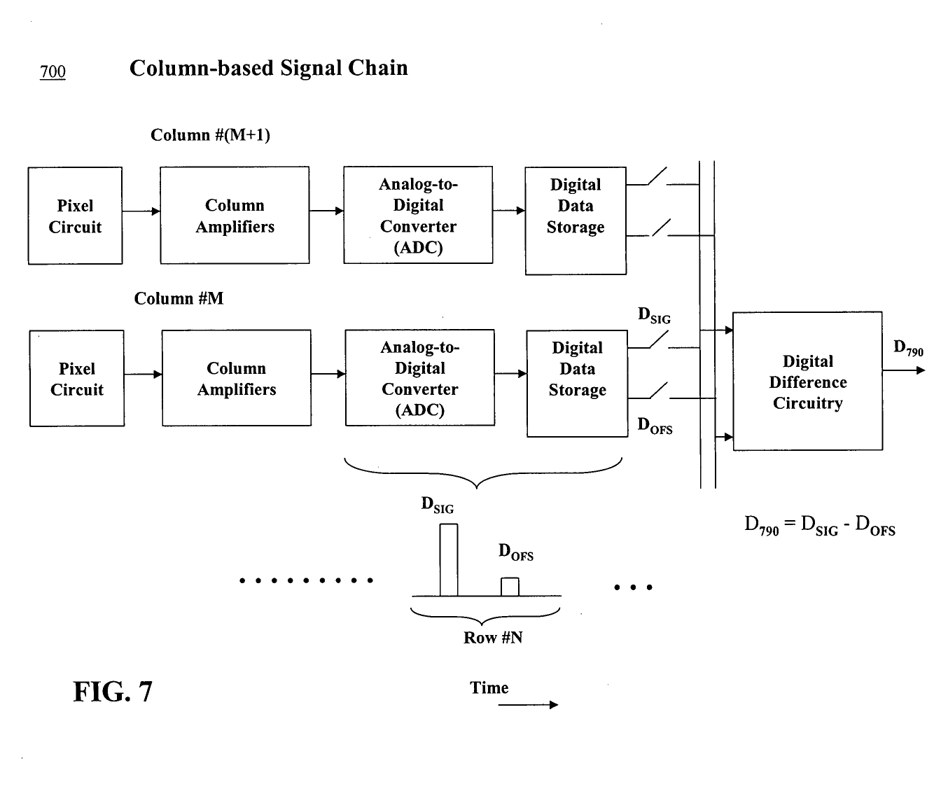

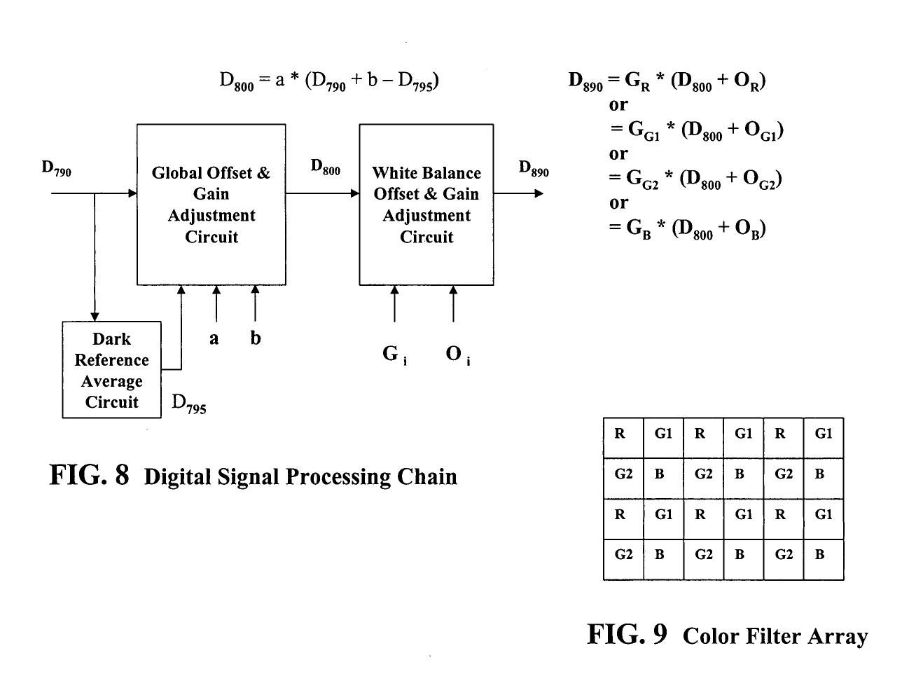

A block diagram of the sensor array circuitry for the two millions pixel array is shown in FIG. 4C. In Applicants' design, 1936×1090 pixels form the pixel array. This sensor design uses architecture with Column-Parallel Analog-to-Digital (ADC), where each column has its own ADC. This architecture is distinctly different from Applicants' 0.3 mega pixel sensor design, where a single ADC is used. In the single ADC design, the conversion frequency runs at the pixel clock rate. For example, in the case of 0.3 mega pixel sensor, the pixel clock rate runs at least 9 MHz to provide 30 frames-per-second video. When the pixel count becomes larger, for example in the case of 2 mega pixels, the single ADC design would require the conversion rate to run at least 60 MHz. For image sensors, typically, the ADC requires to provide 10-bits accuracy. A 10-bit and 60 MHz ADC itself requires the state-of-the-arts design, which may require fabrication beyond a typical CMOS based process. Worse than that, it generates a lot of noise and heat that affect the overall sensor performance. In contrast, Column-Parallel ADC can run at the frequency at “line rate” which, in Applicants' two millions pixel sensor, is about a factor of 1000 slower than the pixel rate. This allows Applicants to use much simpler CMOS-process-compatible ADC designs. Because of the slow conversion rate, the noise and heat can be reduced leading to better sensor performance. In FIG. 4C, the timing control and bias generator circuitry on chip generate all the timing clocks and voltages required to operate the on-chip circuitry. They are to simplify the interface between the sensor and other camera electronics, and they allow sensor users to use a single master clock and single supply voltage that are desirable features in sensor application. In Applicants' two million pixels sensor design, there are two 10-bit video output ports, as shown in FIG. 4C, Dout-Even [9:0] and Dout_Odd [9:0] representing the video output from even columns and odd columns, respectively. Not shown in the Figure is an option that allows the sensor users to select an option to use only a single 10-bit port for video output. This single port design allows Applicants to use a smaller chip carrier because at least ten I/O pins can be removed. However, to support the single-port output, Applicant needs to design a switch that multiplexes the even and odd column video to have the right sequence. This switch needs to operate at higher frequency, and possible higher noise. In some applications, users might want to use two-port output in order to reduce the noise caused by any elements running at high frequency on chip. For reasons such as these, in Applicants' embodiment the choice of single-port vs. two-ports is an option to sensor users. In Applicants' 2 mega-pixel sensor, a serial I/O port is designed to allow sensor users to read and change some of the parameters for running the sensor. Applicants' two million-pixel sensor has 1928×1082 active pixels; surrounding the active pixel region are 4 pixels covered with visible light shield that can be used as the dark reference, shown in FIG. 5. FIG. 6 shows Applicants' design to separate the even and odd columns so one set would come from top and one set would come from the bottom. FIG. 7 shows the column-based signal chain of Applicants' two million pixels sensor design. The signal comes out of the pixel region will be hold and sample into the column amplifier circuit. In the design, sensor users are allowed to program the amplification factor depending upon the signal level. The sensor uses other on-chip intelligence to automatically change the amplification factors. At this point, the signal is still analog in nature. Then this signal goes to the column-based ADC to be converted into digital signal. In Applicants design, there are two ADC conversions, one is for the signal and another one is for the reference. Applicants call this technique Delta Double Sampling (DDS). This technique allow Applicants to remove any offset the signal may experience when its pass physically from the pixel region to ADC region. It reduces the fixed pattern noise, commonly a major weakness for CMOS-based Active Pixel Sensor (APS). After DDS, the offset-cancelled digital signal is fetched into the digital signal processing chain, shown in FIG. 8. The signal goes into the Global Offset and Gain Adjustment Circuit (GOGAC) and Dark Reference Average Circuit (DRAC) at the same time. The DRAC circuit calculates the average in the dark reference pixel region, which can provide the signal level representing Dark. In the GOGAC circuit, the gain and offset are applied to the incoming digital signal. After that the digital signal is fetched into the White Balance Offset and Gain Adjustment Circuit (VWBOGAC). WBOGAC applies a separate gain and offset according to the color filter the pixel is covered with. The purpose of it is to achieve a white-balanced signal under various light-sources. The parameters can be programmed in by the sensor users or by the on-chip intelligence.

### Crosstalk Reduction

With the basic design of the present invention where the photodiode layers are continuous layers covering pixel electrodes, the potential for crosstalk between adjacent pixels is an issue. For example, when one of two adjacent pixels is illuminated with radiation that is much more intense than the radiation received by its neighbor, the electric potential difference between the surface electrode and the pixel electrode of the intensely radiated pixel will become substantially reduced as compared to its less illuminated neighbor. Therefore, there could be a tendency for charges generated in the intensely illuminated pixel to drift over to the neighbor's pixel electrode.

In the case of a three-transistor unit cell design, the photo-generated charge is collected on a capacitor at the unit cell. As this capacitor charges, the voltage at the pixel contact swings from the initial reset voltage to a maximum voltage, which occurs when the capacitor has been fully charged. A typical voltage swing is 1.4V. Due to the continuous nature of Applicant's coating, there is the potential for charge leakage between adjacent pixels when the sense nodes of those pixels are charged to different levels. For example, if a pixel is fully charged and an adjacent pixel is fully discharged, a voltage differential of 1.4V will exist between them. There is a need to isolate the sense nodes among pixels so crosstalk can be minimized or eliminated.

### Gate-Biased Transistor

As explained in Applicant's parent patent application Ser. No. 10/072,637 that has been incorporated herein by reference, a gate-biased transistor can be used to isolate the pixel sense nodes while maintaining all of the pixel electrodes at substantially equal potential so crosstalk is minimized or eliminated. However, an additional transistor in each pixel adds complexity to the pixel circuit and provides an additional means for pixel failure. Therefore, a less complicated means of reducing crosstalk is desirable.

### Increased Resistivity in Bottom Photodiode Layer

Applicants have discovered that crosstalk between pixel electrodes can be significantly reduced or almost completely eliminated in preferred embodiments of the present invention through careful control of the design of the bottom photodiode layer without a need for a gate-biased transistor. The key elements necessary for the control of pixel crosstalk are the spacing between pixel contacts and the thickness and resistivity of the photodiode layers. These elements are simultaneously optimized to control the pixel crosstalk, while maintaining all other sensor performance parameters. The key issues related to each variation are described below.

1. Pixel Contact Spacing

Increased spacing, l, between pixel contacts increases the effective resistance between the pixels, as described in the relationship between resistance and resistivity.

$$R = ρ \frac{l}{t \cdot w} \qquad ( Eq . 1 )$$

The spacing between pixel contacts is a consequence of the designed pixel pitch and pixel contact area. From the geometric configuration alone, we can create a differentiation so carriers would favor one direction over the other. For example, along the vertical direction, the resistance becomes

Rᵥ=ρ×T/(W×L), where ρ is the resistivity, T is the p-layer thickness, W is the pixel width and L is the pixel length.

In most cases W=L, therefore, we can get

Rᵥ=ρ×T/W²

On the other hand, along the lateral direction, the resistance becomes

R₁=ρ/T.

The resistance ratio between lateral and vertical is

R₁/Rᵥ=(W/T)²

This can create a preferred carrier flow direction, favorable in vertical direction, as long as W/T>1. In Applicants' practice, the P-layer thickness is around 0.01 um and pixel width is about 5 um, W/T=500 which is much greater than 1. Of course, the final pixel contact size must be selected based on simultaneous optimization of all sensor performance parameters.

2. Layer Thickness

Decreasing the coating thickness, t, results in an increase in the effective inter-pixel resistance as described in equation 1. In the case of an amorphous silicon N-I-P diode, the layer in question is the bottom P-layer. In the case of an amorphous silicon P-I-N diode, it is the bottom N-layer. In both cases, only the bottom doped layer is considered because the potential barriers that occur at the junctions with the I-layer prevent significant leakage of collected charge back into the I-layer. Also in both cases, there is a practical limit to the minimum layer thickness, beyond which the junction quality is degraded.

3. Coating Resistivity

The parameter in Equation 1 that allows the largest variation in the effective resistance is ρ, the resistivity of the bottom layer. This parameter can be varied over several orders of magnitude by varying the chemical composition of the layer in question. In the case of the amorphous silicon N-layer and P-layer discussed above, the resistivity is controlled by alloying the doped amorphous silicon with carbon and/or varying the dopant concentration. The resulting doped P-layer or N-layer film can be fabricated with resistivity ranging from 100 Ω-cm to more than 10¹¹ Ω-cm. The incorporation of a very high-resistivity doped layer in an amorphous silicon photodiode might decreases the electric field strength within the I-layer, therefore whole sensor performance must be considered when optimizing the bottom doped layer resistivity.

The growth of a high-resistivity amorphous silicon based film can be achieved by alloying the silicon with another material resulting in a wider band gap and thus higher resistivity. It is also necessary that the material not act as a dopant providing free carriers within the alloy. The elements known to alloy with amorphous silicon are germanium, tin, oxygen, nitrogen and carbon. Of these, alloys of germanium and tin result in a narrowed band gap and alloys of oxygen, nitrogen and carbon result in a widened band gap. Alloying of amorphous silicon with oxygen and nitrogen result in very resistive, insulating materials. However, silicon-carbon alloys allow controlled increase of resistivity as a function of the amount of incorporated carbon. Furthermore, silicon-carbon alloy can be doped both N-type and P-type by use of phosphorus and boron, respectively.

Amorphous silicon based films are typically grown by plasma enhanced chemical vapor deposition (PECVD). In this deposition process the film constituents are supplied through feedstock gasses that are decomposed by means of a low-power plasma. Silane or disilane are typically used for silicon feedstock gasses. The carbon for silicon-carbon alloys is typically provided through the use of methane gas, however ethylene, xylene, dimethyl-silane (DMS) and trimethyl-silane (TMS) have also been used to varying degrees of success. Doping may be introduced by means of phosphene or diborane gasses.

### Preferred Process for Making Photodiode Layers

In our current practice for a N-I-P diode, the P-layer, which is making contact with the pixel electrode, has a thickness of about 0.01 microns. The pixel size is 5 microns×5 microns. Because of the aspect ratio between the thickness and pixel width (or length) is much smaller than 1, within the P-layer the resistance along the lateral (along the pixel width/length direction) is substantially higher than the vertical direction, based upon Equation 1. Because of this, the electrical carriers prefer to flow in the vertical direction than in the lateral direction. This alone may not be sufficient to ensure that the crosstalk is low enough. Therefore, Applicants prefer to increase the resistivity by introducing carbon atoms into P-layer to make it become a wider band-gap material. Our P-layer is a hydrogenated amorphous silicon layer with carbon concentration about 10²² atoms/cc. The hydrogen content in this layer is in the order of 10²¹-10²² atoms/cc, and the P-type impurity (Boron) concentration in the order of 10²⁰-10²¹ atoms/cc. This results in a film resistivity of about 10¹⁰ ohm-cm. For a 5 um×5 um pixel, we have found out that negligible pixel crosstalk can be achieved even when the P-layer resistivity is down to about 2-3×10⁷ ohm-cm. Like what is described above, there is a need of engineering trade-off among P-layer thickness, carbon concentration, boron concentration and pixel size to achieve the required overall sensor performance. Therefore, the resistivity requirement may vary for other pixel sizes and configurations. For this N-I-P diode with 5 um×5 um pixel, our I-layer is an intrinsic hydrogenated amorphous silicon with a thickness about 0.5-1 um. The N-layer is also a hydrogenated amorphous silicon layer with N-type impurity (Phosphorous) concentration in the order of 10²⁰ to 10²¹ atoms/cc.

For applications where the polarity of the photodiode layers are reversed and the N-layer is adjacent to the pixel electrode, the carbon atoms/molecules are added to the N-layer to reduce crosstalk.

### Specifications for Two-Million Pixel Sensor

Applicants have built and tested a prototype two-million pixel sensor as shown in FIG. 4A through FIG. 8. This sensor is ideally suited for use as a camera for high definition television. Other applications include: cellular phone cameras, surveillance cameras, embedded cameras on portable computers, PDA cameras and digital still cameras. Applicant's specifications for this sensor are summarized below:

1. Photo-sensing layer:

a. N−1-P photodiode structure;

b. N−1-P is made of hydrogenated amorphous silicon;

c. N-I-P layers are un-patterned;

d. a surface electrode layer covers over the N-I-P layer structure;

e. the surface electrode layer is un-patterned;

f. the surface electrode layer is transparent to visible light;

g. the surface electrode layer is Indium Tin Oxide (ITO);

h. the surface electrode layer is electrically biased to a constant voltage;

i. the constant voltage in Item H is around 3.3V;

j. a conductive pixel electrode covers substantial area of a said pixel;

k. a electrical field is established across the N-I-P layers by applying voltages drop between the surface electrode and metal pixel electrode;

l. P layer is doped with P-type impurity;

m. I-layer is un-intentionally doped intrinsic layer;

n. N layer is doped with n-type impurity;

o. P layer is the layer making electrical and physical contact to the conductive pixel electrode and through the pixel electrode to the underlying CMOS pixel circuitry electrically;

p. P layer is very resistive to avoid pixel-to-pixel crosstalk;

q. the high resistivity in P layer is achieved by adding carbon atoms or molecules into P layer;

r. Item j is made of metal;

s. Item j is made of metallic nitride;

t. Item j is made of Titanium Nitride;

2. Pixel circuitry:

a. has an insulating layer, fabricated with the known semiconductor process, between the conductive pixel electrode and underlying pixel circuitry;

b. has at least one via, passing through the insulating layer, connecting electrically the said pixel electrode to said underlying pixel circuitry;

c. each pixel comprises of a charge collection node, charge sense node, charge storage circuitry, signal reset circuitry and signal readout selection circuitry;

d. each pixel circuit comprises of three transistors;

e. the gate of one of the transistor is electrically connected to the charge sense node;

f. one of the transistor is used for signal reset to a known state;

g. one of the transistor is used for signal readout selection;

h. Another embodiment is not to use Items (a) and (b) and have the pixel electrode making direct physical and electrical contact to the diffusion area of the reset transistor (Item f).

3. Array circuitry:

a. the sensor array has 2 million pixels;

b. each pixel is 5 um×5 um;

c. the 2 million pixels is formed as 1928 (columns)×1082 (rows) active area;

d. minimum four metal covered pixels, 4 pixels wide, surround the active area;

e. the metal covered pixels are used to establish a dark reference for the array;

f. each column has an analog-to-digital converter (ADC);

g. each column has circuits for signal condition, signal amplification and sample-and-hold;

h. the array is arranged to have the signal of even columns and odd columns coming out of from the top and bottom of the array, separately;

i. Items F and G are designed to with the width of two pixels wide;

j. A delta double sampling (DDS) scheme is used to sample the signal and reference voltages consecutively;

k. the sampled signal and reference voltages are converted by the column ADC into digital signals;

l. the difference between the said signals in Item k determines the light level detected by the photo-sensing device;

m. there are two output data ports, one for even columns and one for odd columns

n. the sensor has on-chip circuit to multiplex the even and odd column output to make a pixel-sequential video output through a single port;

o. the sensor has on-chip circuit to accept one single voltage input and generates all bias voltages needed to run various circuits on chip;

p. the sensor has an option not to use the circuit of Item O but to accept multiple voltage inputs to run various circuits on chip;

q. Item G has circuitry providing the selection of multiple signal amplification factors;

r. the multiple signal amplification factor covers 1×to 8×, with 256 increments;

s. the fine increment of amplification factor is to allow fine adjustment for auto exposure control;

t. the sensor array can be covered with color filter;

u. the color filters comprises of Red, Green and Blue filters;

v. the color filter array is arranged with four pixels as a unit, the upper-left pixel covered with Red filter, the upper-right covered with Green filter, the lower-left covered with Green filter and the lower-right covered with Blue filter;

w. there is a timing circuitry on the same chip, which provides all the clocks necessary to operate the pixel and readout circuitry;

x. the timing circuitry also provides the synchronization (pixel, line and frame) signals which enables other chips to interface with this image sensor;

y. the timing circuitry also provide timing control for light exposure time;

z. there are circuits on chip to provide some of the bias voltage to operate other parts of the circuit;

aa. the array and pixel circuits are fabricated with CMOS process.

### Variations

Two preferred embodiment of the present invention have been described in detail above. However, many variations from that description may be made within the scope of the present invention. For example, the three-transistor pixel design described above could be replaced with more elaborate pixel circuits (including 4, 5 and 6 transistor designs) described in detail the parent applications. The additional transistors provide certain advantages as described in the referenced applications at the expense of some additional complication. The photoconductive layers described in detail above could be replaced with other electron-hole producing layers as described in the parent application or in the referenced '353 patent. The photodiode layer could be reversed so that the p-doped layer is on top and the n-doped layer is on the bottom in which case the charges would flow through the layers in the opposite direction. The transparent layer could be replaced with a grid of extremely thin conductors. The readout circuitry and the camera circuits 140-148 as shown in FIG. 2 could be located partially or entirely underneath the CMOS pixel array to produce an extremely tiny camera. The CMOS circuits could be replaced partially or entirely by MOS circuits. Some of the circuits 140-148 shown on FIG. 2 could be located on one or more chips other than the chip with the sensor array. For example, there may be cost advantages to separate the circuits 144 and 146 onto a separate chip or into a separate processor altogether. The number of pixels could be decreased below 0.3 mega-pixels or increased above 2 million almost without limit.

### Other Camera Applications

This invention provides a camera potentially very small in size, potentially very low in fabrication cost and potentially very high in quality. Naturally there will be some tradeoffs made among size, quality and cost, but with the high volume production costs in the range of a few dollars, a size measured in millimeters and image quality measured in mega-pixels or fractions of mega-pixels, the possible applications of the present invention are enormous. Some potential applications in addition to cell phone cameras are listed below:

Analog camcorders

Digital camcorders

Security cameras

Digital still cameras

Personal computer cameras

Toys

Endoscopes

Military unmanned aircraft, bombs and missiles

Sports

High definition Television sensor

### Eyeball Camera

Since the camera can be made smaller than a human eyeball, one embodiment of the present invention is a camera fabricated in the shape of a human eyeball. Since the cost will be low the eyeball camera can be incorporated into many toys and novelty items. A cable may be attached as an optic nerve to take image data to a monitor such as a personal computer monitor. The eyeball camera can be incorporated into dolls or manikins and even equipped with rotational devices and a feedback circuit so that the eyeball could follow a moving feature in its field of view. Instead of the cable the image data could be transmitted wirelessly using cell phone technology.

### A Close-Up View of a Football Game

The small size of these cameras permits them along with a cell phone type transmitter to be worn (for example) by professional football players installed in their helmets. This way TV fans could see the action of professional football the way the players see it. In fact, the camera plus a transmitter could even be installed in the points of the football itself that could provide some very interesting action views. These are merely examples of thousands of potential applications for these tiny, inexpensive, high quality cameras.

While there have been shown what are presently considered to be preferred embodiments of the present invention, it will be apparent to those skilled in the art that various changes and modifications can be made herein without departing from the scope and spirit of the invention. For example, this camera can be used without the lens to monitor the light intensity profile and output the change of intensity and profile. This is crucial in optical communication application where beam profile needs to be monitored for highest transmission efficiency. This camera can be used to extend light sensing beyond visible spectrum when the amorphous-Silicon is replaced with other light sensing materials. For example, one can use microcrystalline-Silicon to extend the light sensing toward near-infrared range. Such camera is well suitable for night vision. In the preferred embodiment, we use a package where senor is mounted onto a chip carrier on which is clicked onto a lens housing. One can also change the assembly sequence by solder the sensor onto a sensor board first, then put the lens holder with lens to cover the sensor and then mechanically fasten onto the PCB board to make a camera. This is a natural variation from this invention to those skilled in the art.

Thus, the scope of the invention is to be determined by the appended claims and their legal equivalents.

What is claimed is:

1. A MOS or CMOS based active sensor array comprising:
A) a substrate,
B) a plurality of MOS or CMOS pixel circuits fabricated in or on said substrate, each pixel circuit comprising:
1) a charge collecting electrode for collecting electrical charges and
2) at least three transistors for monitoring periodically charges collected by said charge collecting electrode,
C) a photodiode layer of charge generating material located above said pixel circuits for converting electromagnetic radiation into electrical charges, said photodiode layer comprising an N-doped layer, a P-doped layer and an intrinsic layer in between said P-doped layer and said N-doped layer, wherein one of said N-doped layer or said P-doped layer defines a bottom photodiode layer, is in electrical contact with said charge collecting electrode and is configured to avoid any significant pixel to pixel crosstalk,
D) a surface electrode in the form of a thin transparent layer or grid located above said layer of charge generating material;
wherein electrical charges generated in regions of said photodiode layer above a particular charge collecting electrode are collected by that particular charge collecting electrode and no significant portion of said of the electrical charges generated above that particular charge collecting electrode are collected by any other charge collecting electrode.

2. An array as in claim 1 wherein said bottom photodiode layer comprises carbon.

3. An array as in claim 2 wherein said carbon in said bottom layer represents a concentration of less than 50 percent.

4. An array as in claim 2 wherein said carbon in said bottom layer represents a concentration of between about 5 to 35 percent.

5. An array as in claim 1 wherein said bottom layer is no thicker than about 0.1 micron.

6. An array as in claim 3 wherein said bottom layer is no thicker than about 0.1 micron.

7. An array as in claim 1 wherein electrical resistivity between adjacent pixels is greater than about 10⁷ ohm-cm.

8. An array as in claim 3 wherein voltage differential between adjacent charge collecting electrodes varies within a range of about 0 to 2 Volts.

9. An array as in claim 3 wherein said bottom layer is a P-doped layer.

10. An array as in claim 3 wherein said bottom layer is an N-doped layer.

11. An array as in claim 1 wherein said bottom layer is configured to avoid any significant pixel to pixel crosstalk by minimizing thickness of said bottom layer and adjusting the resistivity of material comprising the bottom layer.

12. An array as in claim 1 wherein said plurality of pixel circuits is at least 0.3 million pixel circuits.

13. An array as in claim 1 wherein said plurality of pixel circuits is at least 2 million pixel circuits.

14. An array as in claim 1 and also comprising image manipulation circuits fabricated on said substrate.

15. An array as in claim 14 and also comprising data analyzing circuits fabricated on said substrate.

16. An array as in claim 14 and also comprising input and output interface circuits fabricated on said substrate.

17. An array as in claim 16 and also comprising decision and control circuits fabricated on said substrate.

18. An array as in claim 16 and also comprising communication circuits fabricated on said substrate.

19. An array as in claim 1 wherein said sensor is configured with a Column-Parallel Analog-to Digital architecture.

20. An array as in claim 1 where said array is a component of a video camera and said array further comprises two 10-bit output ports representing video output from columns and odd columns respectively.

21. An array as in claim 1 wherein a plurality of said pixel circuits are covered wit a visible light shield and are configured to operate as dark references.

22. An array as in claim 21 and further two ADC conversions to reduce fixed pattern noise.

23. An array as in claim 1 and further comprising a gain adjustment circuit to produce white-balanced signals under various light sources.

24. An array as in claim 1 wherein said array is an integral part of a camera attached by a cable to a cellular phone.

25. An array as in claim 1 wherein said surface electrode is comprised of a layer of indium tin oxide.

26. An array as in claim 1 wherein said array in an integral part of a camera in a cellular phone.

27. An array as in claim 1 and further comprising an array of color filters located on top of said surface electrode.

28. An array as in claim 27 wherein said color filters are comprised of red, green and blue filters arranged in four color quadrants of two green, one red and one blue.

29. An array as in claim 1 wherein said array is a part of a camera fabricated in to form of a human eyeball.

30. An array as in claim 18 wherein said decision and control circuits comprise a processor programmed with a control algorithm for analyzing pixel data and based on that data controlling signal output from said sensor array.

31. An array as in claim 30 wherein said processor controls signal output by adjusting pixel illumination time.

32. An array as in claim 30 wherein said processor controls signal output by adjusting signal amplification.

33. An array as in claim 1 wherein said array is a part of a camera incorporated into a device chosen from the following group:
Analog camcorder
Digital camcorder
Security camera
Digital still camera
Personal computer camera
Toy
Endoscope
Military unmanned aircraft, bomb and missile
Sports equipment
High definition television camera

34. A camera with a MOS or CMOS based active sensor array for producing electronic images from electron-hole producing light, said camera comprising:
A) an active sensor array fabricated on or in a substrate, said sensor array comprising:
A) a layer of charge generating material for converting the electron-hole producing light into electrical charges,
B) a plurality of MOS or CMOS pixel circuits, each pixel circuit comprising a charge collecting electrode, located under the layered photodiodes for collecting the charges, and
C) a surface electrode in the form of a thin transparent layer or grid located above said layer of charge generating material,
B) additional MOS or CMOS circuits in and/or on the same crystalline substrate with said active sensor array for converting the charges into images, and
C) focusing optics for focusing electron-hole producing light onto said active sensor array.

35 A camera as in claim 34 wherein said plurality of MOS or CMOS pixel circuits is a plurality of CMOS pixel circuits.

36. A camera as in claim 34 wherein said plurality of pixels is at least 0.3 million pixels.

37. A camera as in claim 34 and also comprising image manipulation circuits fabricated on said substrate.

38. A camera as in claim 37 and also comprising data analyzing circuits fabricated on said substrate.

39. A camera as in claim 37 and also comprising input and output interface circuits fabricated on said substrate.

40. A camera as in claim 39 and also comprising decision and control circuits fabricated on said substrate.

41. A camera as in claim 39 and also comprising communication circuits fabricated on said substrate.

42. A camera as in claim 34 wherein said camera is fabricated in to form of a human eyeball.

43. A camera as in claim 34 wherein said camera is incorporated into a device chosen from the following group:
Analog camcorder
Digital camcorder
Security camera
Digital still camera
Personal computer camera
Toy
Endoscope
Military unmanned aircraft, bomb and missile
Sports equipment
High definition television camera

44. A high definition MOS or CMOS based camera comprising:
A) a MOS or CMOS based active sensor array comprising:
1) a substrate,
2) at least two million MOS or CMOS pixel circuits fabricated in or on said substrate, each pixel circuit comprising:
3) a charge collecting electrode for collecting electrical charges and at least three transistors for monitoring periodically charges collected by said charge collecting electrode,
4) a photodiode layer of charge generating material located above said pixel circuits for converting electromagnetic radiation into electrical charges, said photodiode layer comprising an N-doped layer, a P-doped layer and an intrinsic layer in between said P-doped layer and said N-doped layer, wherein one of said N-doped layer or said P-doped layer defines a bottom photodiode layer, is in electrical contact with said charge collecting electrode and is configured to avoid any significant pixel to pixel crosstalk,
5) a surface electrode in the form of a thin transparent layer or grid located above said layer of charge generating material;
wherein electrical charges generated in regions of said photodiode layer above a particular charge collecting electrode are collected by that particular charge collecting electrode and no significant portion of said of the electrical charges generated above that particular charge collecting electrode are collected by any other charge collecting electrode,

45. An array as in claim 44 wherein said bottom photodiode layer comprises carbon.

46. An array as in claim 45 wherein said carbon in said bottom layer represents a concentration of between about 5 to 35 percent.

47. An array as in claim 44 wherein said bottom layer is no thicker than about 0.1 micron.

48. An array as in claim 44 wherein said bottom layer is no thicker than about 0.1 micron.

49. An array as in claim 44 wherein said sensor is configured with a Column-Parallel Analog-to Digital architecture.

50. An array as in claim 1 where said array is a component of a video camera and said array further comprises two 10-bit output ports representing video output from columns and odd columns respectively.

51. An array as in claim 44 wherein a plurality of said pixel circuits are covered wit a visible light shield and are configured to operate as dark references.

52. An array as in claim 51 and further comprising two ADC conversions to reduce fixed pattern noise.

53. An array as in claim 44 and further comprising a gain adjustment circuit to produce white-balanced signals under various light sources.

54. An array as in claim 1 wherein said plurality of MOS or CMOS pixel circuits is a plurality of CMOS pixel circuits.

55. An array as in claim 34 wherein said plurality of MOS or CMOS pixel circuits is a plurality of CMOS pixel circuits.

56. An array as in claim 44 wherein said at least two million MOS or CMOS pixel circuits are at least two million CMOS pixel circuits.
